(19) United States
(12) Patent Application Publication
(10) Pub. No.: US 2024/0282752 A1
(43) Pub. Date: Aug. 22, 2024

(54) SEMICONDUCTOR PACKAGE

(71) Applicant: SAMSUNG ELECTRONICS CO., LTD, Suwon-si (KR)

(72) Inventors: Yeonjin LEE, Suwon-si (KR); Jong-Min LEE, Suwon-si (KR)

(73) Assignee: SAMSUNG ELECTRONICS CO., LTD, Suwon-si (KR)

(21) Appl. No.: 18/509,685

(22) Filed: Nov. 15, 2023

(30) Foreign Application Priority Data
Feb. 21, 2023 (KR) 10-2023-0022852

(51) Int. Cl. H01L 25/065; H01L 23/00; H01L 23/31; H10B 80/00

(52) U.S. Cl. CPC H01L 25/0657; H01L 23/3135; H01L 24/09; H01L 24/16; H01L 24/32; H01L 24/73; H10B 80/00; H01L 24/97; H01L 25/0652; H01L 2224/0903; H01L 2224/16148; H01L 2224/16227; H01L 2224/32145; H01L 2224/32225; H01L 2224/73204; H01L 2224/97; H01L 2225/06513; H01L 2225/06541; H01L 2924/381

(57) ABSTRACT

Provided is a semiconductor package, including a semiconductor substrate including a plurality of first vias, a chip stack on the semiconductor substrate, the chip stack including first semiconductor chips on the semiconductor substrate, and a second semiconductor chip on an uppermost first semiconductor chip of the first semiconductor chips, and a mold layer on the semiconductor substrate and the chip stack, and exposing a top surface of the chip stack, wherein a first thickness of the semiconductor substrate is greater than a second thickness of each of the first semiconductor chips, wherein a third thickness of the second semiconductor chip is less than or equal to the second thickness of each of the first semiconductor chips, wherein the semiconductor substrate further includes lower substrate pads on a bottom surface of the semiconductor substrate, wherein each of the first semiconductor chips includes lower chip pads on a bottom surface of each of the first semiconductor chips, and wherein a first width of each of the lower substrate pads is greater than a second width of each of the lower chip pads.

### CROSS-REFERENCE TO RELATED APPLICATIONS

This application claims priority to Korean Patent Application No. 10-2023-0022852, filed on Feb. 21, 2023, in the Korean Intellectual Property Office, the disclosure of which is incorporated by reference herein in its entirety.

### BACKGROUND

Embodiments of the present disclosure relate to a semiconductor package and a method of fabricating the same, and in particular, to a stack-type semiconductor package, in which a plurality of semiconductor chips are disposed on a substrate, and a method of fabricating the same.

With recent advancements in the electronics industry, there is an increasing demand for high-performance, high-speed, and compact electronic components. In response to this trend, packaging technologies of mounting a plurality of semiconductor chips in a single package are being developed.

Recently, a demand for portable electronic devices has been rapidly increasing in the market, and thus, it is necessary to reduce sizes and weights of electronic components constituting the portable electronic devices. To achieve this, it is necessary to develop packaging technologies that reduce the size and weight of each component and integrate a plurality of individual components in a single package.

In the semiconductor industry, various package technologies have been developed in response to an increase in demand for large-capacity, thin, and small semiconductor devices and/or electronic products therewith. For example, a package technology of vertically stacking semiconductor chips has been suggested to realize a high-density chip stacking structure. This technology makes it possible to integrate semiconductor chips of various functions on a small area, compared with a typical package provided in the form of a single semiconductor chip. However, various technical problems occur as the number of the disposed semiconductor chips increases.

### SUMMARY

One or more embodiments provide a semiconductor package with an increase integration density.

One or more embodiments also provide a semiconductor package with a reduced size.

One or more embodiments also provide a semiconductor package with improved structural stability and improved heat-dissipation characteristics.

According to an aspect of an embodiment, there is provided a semiconductor package, including a semiconductor substrate including a plurality of first vias, a chip stack on the semiconductor substrate, the chip stack including first semiconductor chips on the semiconductor substrate, and a second semiconductor chip on an uppermost first semiconductor chip of the first semiconductor chips, and a mold layer on the semiconductor substrate and the chip stack, and exposing a top surface of the chip stack, wherein a first thickness of the semiconductor substrate is greater than a second thickness of each of the first semiconductor chips, wherein a third thickness of the second semiconductor chip is less than or equal to the second thickness of each of the first semiconductor chips, wherein the semiconductor substrate further includes lower substrate pads on a bottom surface of the semiconductor substrate, wherein each of the first semiconductor chips includes lower chip pads on a bottom surface of each of the first semiconductor chips, and wherein a first width of each of the lower substrate pads is greater than a second width of each of the lower chip pads.

According to another aspect of an embodiment, there is provided a semiconductor package, including a semiconductor substrate including a plurality of first vias, semiconductor chips on the semiconductor substrate, each of the semiconductor chips including second vias vertically penetrating the semiconductor chips, and a mold layer on the semiconductor substrate and the semiconductor chips, and exposing a top surface of an uppermost semiconductor chip of the semiconductor chips, wherein a first width of the semiconductor substrate is greater than a second width of the chip stack in a horizontal direction, wherein the semiconductor substrate has a first thickness in a vertical direction, wherein the semiconductor chips have second thicknesses, which are equal to each other, in the vertical direction, and wherein the first thickness is greater than the second thicknesses.

According to another aspect of an embodiment, there is provided a semiconductor package, including a substrate, first semiconductor chips on the substrate, and a second semiconductor chip on an uppermost first semiconductor chip of the first semiconductor chips, wherein each of the first semiconductor chips includes upper pads on a top surface each of the first semiconductor chips, first lower pads on a bottom surface each of the first semiconductor chips, and first vias vertically penetrating the first semiconductor chips and connecting the upper pads to the first lower pads, respectively, wherein the second semiconductor chip includes second lower pads a bottom surface of the second semiconductor chip, wherein first terminals on the first lower pads are between a lowermost first semiconductor chip of the first semiconductor chips and the substrate, wherein a first thickness of each of the first semiconductor chips is equal to a second thickness of the second semiconductor chip, wherein side surfaces of the first semiconductor chips are coplanar to a side surface of the second semiconductor chip, and wherein the second thicknesses of the semiconductor chips range from 20 μm to 40 μm.

### BRIEF DESCRIPTION OF DRAWINGS

Embodiments will be more clearly understood from the following detailed description taken in conjunction with the accompanying drawings in which:

FIG. 1 is a sectional view illustrating a semiconductor package according to an embodiment;

FIG. 2 is an enlarged sectional view of a portion ‘A’ of FIG. 1;

FIG. 3 is an enlarged sectional view of a portion ‘B’ of FIG. 1;

FIG. 4 is a sectional view illustrating a semiconductor package according to an embodiment;

FIG. 5 is an enlarged sectional view of a portion ‘C’ of FIG. 4;

FIG. 6 is a sectional view illustrating a semiconductor package according to an embodiment;

FIG. 7 is an enlarged sectional view of a portion ‘D’ of FIG. 6;

FIG. 8 is an enlarged sectional view of a portion ‘E’ of FIG. 6;

FIGS. 9 to 11 are sectional views, each of which illustrates a semiconductor package according to an embodiment;

FIG. 12 is a sectional view illustrating a semiconductor module according to an embodiment; and

FIGS. 13, 14, 15, 16, 17, 18, 19, and 20 are sectional views illustrating a method of fabricating a semiconductor package, according to an embodiment.

### DETAILED DESCRIPTION

Example embodiments will now be described more fully with reference to the accompanying drawings, in which example embodiments are shown.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

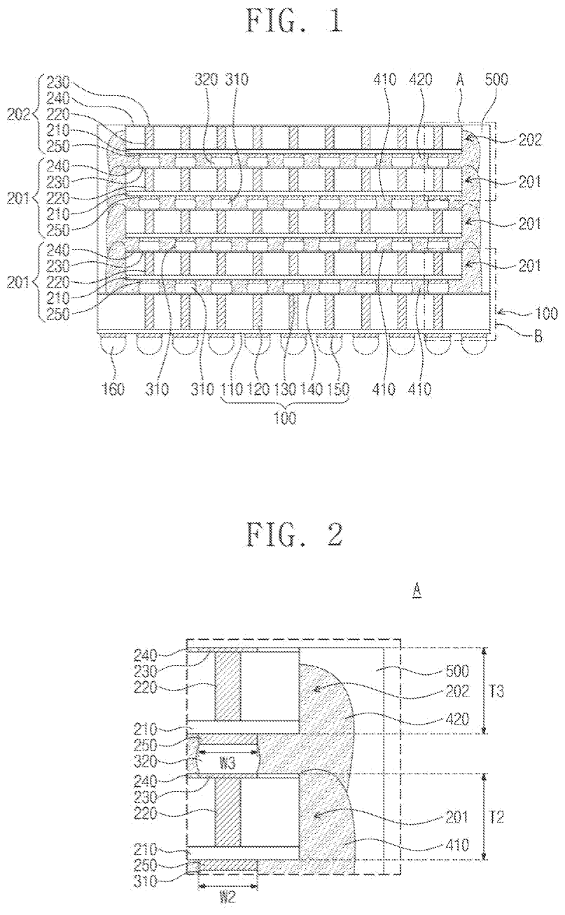

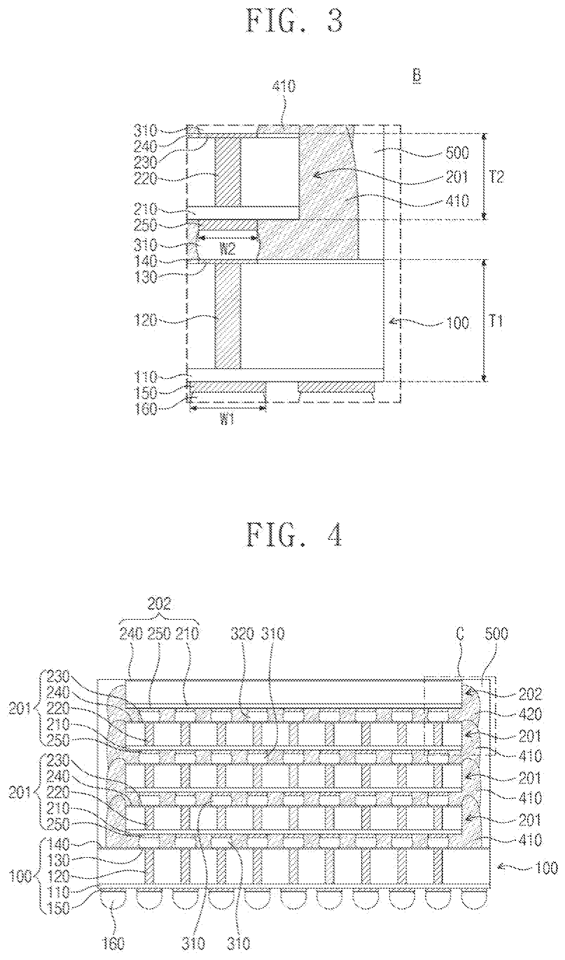

FIG. 1 is a sectional view illustrating a semiconductor package according to an embodiment. FIG. 2 is an enlarged sectional view of a portion ‘A’ of FIG. 1. FIG. 3 is an enlarged sectional view of a portion ‘B’ of FIG. 1.

A semiconductor package according to an embodiment may be a stack-type package, in which via patterns are used. For example, semiconductor chips of the same type may be disposed (stacked) on a base substrate, and the semiconductor chips may be electrically connected to each other through via patterns, which are provided to penetrate the semiconductor chips. The semiconductor chips may be coupled to each other using chip terminals, which are provided on bottom surfaces of the semiconductor chips.

Referring to FIGS. 1 to 3, a base substrate 100 may be provided. The base substrate 100 may be a semiconductor substrate. The base substrate 100 may include an integrated circuit which is provided therein. For example, the base substrate 100 may be a first semiconductor chip including an electronic element (e.g., a transistor). For example, the base substrate 100 may be a wafer-level die formed of a semiconductor material (e.g., silicon (Si)). Although FIG. 1 illustrates an example in which the base substrate 100 is a first semiconductor chip, embodiments are not limited thereto. In an embodiment, the base substrate 100 may be a substrate (e.g., a printed circuit board (PCB)), in which an electronic element (e.g., a transistor) is not provided. A silicon wafer may be thinner than a printed circuit board (PCB). Hereinafter, the base substrate 100 may be referred to as a first semiconductor chip 100.

A first thickness T1 of the first semiconductor chip 100 in a vertical direction (stacking direction) may range from 30 μm to 60 μm. The first semiconductor chip 100 may include a first circuit layer 110, a first via 120, a first upper pad 130, a first protection layer 140, and a first lower pad 150.

The first circuit layer 110 may be provided on a bottom surface of the first semiconductor chip 100. The first circuit layer 110 may include the integrated circuit. For example, the first circuit layer 110 may include a memory circuit, a logic circuit, or combinations thereof. The bottom surface of the first semiconductor chip 100 may be an active surface.

The first via 120 may be provided to vertically penetrate the first semiconductor chip 100. For example, the first via 120 may be extended toward a top surface of the first semiconductor chip 100 and may be exposed to the outside of the first semiconductor chip 100 near the top surface of the first semiconductor chip 100. The first via 120 may be extended to the first circuit layer 110 and may be connected to the first circuit layer 110. The first via 120 and the first circuit layer 110 may be electrically connected to each other. In an embodiment, a plurality of first vias 120 may be provided. An insulating layer may be provided to enclose the first via 120. For example, the insulating layer may be formed of or include at least one of silicon oxide (SiO), silicon nitride (SiN), silicon oxynitride (SiON), or low-k dielectric materials. According to another embodiment, a seed layer or a barrier layer may be provided to cover a side surface and a bottom surface of the first via 120. For example, the seed layer may be formed of or include gold (Au). For example, the barrier layer may be formed of or include titanium nitride (TiN) or tantalum nitride (TaN).

The first upper pad 130 may be disposed on the top surface of the first semiconductor chip 100. The first upper pad 130 may be coupled to the first via 120. In an embodiment, a plurality of first upper pads 130 may be provided. In this case, the first upper pads 130 may be coupled to the first vias 120, respectively, and may be arranged in the same shape as the first vias 120. The first upper pad 130 may be electrically connected to the first circuit layer 110 through the first via 120. The first upper pad 130 may be formed of or include at least one of metallic materials (e.g., copper (Cu), aluminum (Al), and/or nickel (Ni)).

The first protection layer 140 may be disposed on the top surface of the first semiconductor chip 100 to enclose the first upper pad 130. The first protection layer 140 may expose the first upper pad 130. A top surface of the first protection layer 140 and a top surface of the first upper pad 130 may be substantially flat and may be substantially coplanar with each other. According to another embodiment, the first upper pad 130 may have a protruding portion, which is extended to a level higher than the top surface of the first protection layer 140 in the vertical direction, or the first protection layer 140 may be extended to the top surface of the first upper pad 130 to cover an edge portion of the first upper pad 130 and expose a center portion of the first upper pad 130. The first semiconductor chip 100 may be protected by the first protection layer 140. The first protection layer 140 may be formed of or include at least one of oxide, nitride, or oxynitride materials, which contain a semiconductor element included in the first semiconductor chip 100. For example, the first protection layer 140 may be formed of or include at least one of silicon oxide (SiO), silicon nitride (SiN), silicon oxynitride (SiON), or combinations thereof. The first protection layer 140 may be an insulating coating layer containing an epoxy resin, a solder resist layer, or a photosensitive resin layer.

The first lower pad 150 may be disposed on the bottom surface of the first semiconductor chip 100. For example, the first lower pad 150 may be disposed on a bottom surface of the first circuit layer 110. The first lower pad 150 may be electrically connected to the first circuit layer 110. In an embodiment, a plurality of first lower pads 150 may be provided. The first lower pad 150 may have a first width W1 in a horizontal direction. The first lower pad 150 may be formed of or include at least one of metallic materials (e.g., copper (Cu), aluminum (Al), and/or nickel (Ni)).

The first semiconductor chip 100 may further include a lower protection layer. The lower protection layer may be disposed on the bottom surface of the first semiconductor chip 100 to cover the first circuit layer 110. The first circuit layer 110 may be protected by the protection layer. The protection layer may expose a bottom surface of the first lower pad 150, on the bottom surface of the first circuit layer 110. The protection layer may be formed of or include, for example, silicon oxide (SiO) or silicon nitride (SiN).

An outer terminal 160 may be provided on the bottom surface of the first semiconductor chip 100. The outer terminal 160 may be disposed on the first lower pad 150. The outer terminal 160 may be electrically connected to the first circuit layer 110 and the first via 120. In an embodiment, the outer terminal 160 may be disposed below the first via 120. In this case, the first via 120 may be provided to penetrate the first circuit layer 110 and may be exposed to the outside of the first circuit layer 110 near the bottom surface of the first circuit layer 110, and the outer terminal 160 may be directly coupled to the first via 120. For example, the first lower pad 150 may not be provided below the first circuit layer 110. The following description will be given based on the embodiment of FIG. 1. In an embodiment, a plurality of outer terminals 160 may be provided. In this case, the outer terminals 160 may be coupled to the first lower pads 150, respectively. The outer terminal 160 may be formed of or include an alloy that contains at least one of tin (Sn), silver (Ag), copper (Cu), nickel (Ni), bismuth (Bi), indium (In), antimony (Sb), or cerium (Ce).

A chip stack may be disposed on the first semiconductor chip 100. A width of the chip stack may be smaller than a width of the first semiconductor chip 100 in the horizontal direction. The chip stack may include a plurality of second semiconductor chips 201 and 202. The second semiconductor chips 201 and 202 may be of the same type. For example, each of the second semiconductor chips 201 and 202 may be a memory chip. The chip stack may include lower semiconductor chips 201, which are disposed on the first semiconductor chip 100, and an upper semiconductor chip 202, which is disposed on the lower semiconductor chips 201. The lower semiconductor chips 201 and the upper semiconductor chip 202 may be sequentially disposed on the first semiconductor chip 100. As an example, the upper semiconductor chip 202 may be the uppermost semiconductor chip in the chip stack, and the lower semiconductor chips 201 may be remaining semiconductor chips, which are placed below the upper semiconductor chip 202. The lower semiconductor chips 201 may be sequentially disposed between the first semiconductor chip 100 and the upper semiconductor chip 202.

A detailed structure of the lower semiconductor chips 201 will be described with reference to one lower semiconductor chip 201. A width of the lower semiconductor chip 201 may be smaller than the width of the first semiconductor chip 100 in the horizontal direction. A second thickness T2 of the lower semiconductor chip 201 may be smaller than the first thickness T1 of the first semiconductor chip 100 in the vertical direction. The second thickness T2 of the lower semiconductor chip 201 may range from 20 μm to 40 μm.

The lower semiconductor chip 201 may include a second circuit layer 210, a second via 220, a second upper pad 230, a second protection layer 240, and a second lower pad 250.

The lower semiconductor chip 201 may have the second circuit layer 210 facing the first semiconductor chip 100. The second circuit layer 210 may include the afore-described integrated circuit. For example, the second circuit layer 210 may include a memory circuit. For example, a bottom surface of the lower semiconductor chip 201 may be an active surface.

The second via 220 may be provided to vertically penetrate the lower semiconductor chip 201 in a direction from the second protection layer 240 toward the second circuit layer 210. For example, the second via 220 may be extended toward a top surface of the lower semiconductor chip 201 and may be exposed to the outside of the lower semiconductor chip 201 near the top surface of the lower semiconductor chip 201. The second via 220 may be extended toward the second circuit layer 210 and may be connected to the second circuit layer 210. The second via 220 and the second circuit layer 210 may be electrically connected to each other. In an embodiment, a plurality of second vias 220 may be provided. An insulating layer may be provided to enclose the second via 220. The insulating layer may be formed of or include at least one of silicon oxide (SiO), silicon nitride (SiN), silicon oxynitride (SiON), or low-k dielectric materials. According to another embodiment, a seed layer or a barrier layer may be provided to cover a side surface and a bottom surface of the second via 220. The seed layer may be formed of or include, for example, gold (Au). The barrier layer may be formed of or include, for example, titanium nitride (TiN) or tantalum nitride (TaN).

The second upper pad 230 may be disposed on the top surface of the lower semiconductor chip 201. The second upper pad 230 may be coupled to the second via 220. In an embodiment, a plurality of second upper pads 230 may be provided. In this case, the second upper pads 230 may be coupled to the second vias 220, respectively, and may be arranged in the same shape as the second vias 220. The second upper pad 230 may be electrically connected to the second circuit layer 210 through the second via 220. The second upper pad 230 may be formed of or include at least one of metallic materials (e.g., copper (Cu), aluminum (Al), and/or nickel (Ni)).

The second protection layer 240 may be disposed on the top surface of the lower semiconductor chip 201 to enclose the second upper pad 230. The second protection layer 240 may expose the second upper pad 230. A top surface of the second protection layer 240 and a top surface of the second upper pad 230 may be substantially flat and may be substantially coplanar with each other. According to another embodiment, the second upper pad 230 may have a protruding portion, which is extended to a level higher than the top surface of the second protection layer 240 in the vertical direction, or the second protection layer 240 may be extended to the top surface of the second upper pad 230 to cover an edge portion of the second upper pad 230 and expose a center portion of the second upper pad 230. The lower semiconductor chip 201 may be protected by the second protection layer 240. The second protection layer 240 may be formed of or include at least one of oxide, nitride, or oxynitride materials, which contain a semiconductor element included in the lower semiconductor chip 201. For example, the second protection layer 240 may be formed of or include at least one of silicon oxide (SiO), silicon nitride (SiN), silicon oxynitride (SiON), or combinations thereof. The second protection layer 240 may be an insulating coating layer containing an epoxy resin, a solder resist layer, or a photosensitive resin layer.

The second lower pad 250 may be disposed on the bottom surface of the lower semiconductor chip 201. For example, the second lower pad 250 may be disposed on a bottom surface of the second circuit layer 210. The second lower pad 250 may be electrically connected to the second circuit layer 210. The second lower pad 250 may have a second width W2 in the horizontal direction. The second width W2 of the second lower pad 250 may be smaller than the first width W1 of the first lower pad 150. In an embodiment, a plurality of second lower pads 250 may be provided. The second lower pad 250 may be formed of or include at least one of metallic materials (e.g., copper (Cu), aluminum (Al), and/or nickel (Ni)).

The lower semiconductor chip 201 may further include a lower protection layer. The lower protection layer may be disposed on the bottom surface of the lower semiconductor chip 201 to cover the second circuit layer 210. The second circuit layer 210 may be protected by the protection layer. The protection layer on the bottom surface of the second circuit layer 210 may be provided to expose a bottom surface of the second lower pad 250. The protection layer may be formed of or include silicon oxide (SiO) or silicon nitride (SiN).

The lower semiconductor chips 201 may have the same structure, for example, the elements have the same physical properties (e.g., size and shape) as each other.

Adjacent ones of the first and lower semiconductor chips 100 and 201 may be connected to each other by first chip terminals 310. For example, the first chip terminals 310 may connect the first semiconductor chip 100 to the lowermost one of the lower semiconductor chips 201 of the chip stack and/or may connect adjacent ones of the lower semiconductor chips 201 to each other. For example, some of the first chip terminals 310 may be disposed between the first upper pad 130 of the first semiconductor chip 100 and the second lower pad 250 of the lowermost one of the lower semiconductor chips 201. Some of the first chip terminals 310 may connect the first upper pad 130 to the second lower pad 250. Others of the first chip terminals 310, which are placed between the lower semiconductor chips 201, may be disposed between the second upper pad 230 and the second lower pad 250. In an embodiment, a plurality of first chip terminals 310 may be provided between the first semiconductor chip 100 and the lowermost one of the lower semiconductor chips 201 and between the lower semiconductor chips 201. The first chip terminals 310 may electrically connect the first semiconductor chip 100 to the lower semiconductor chips 201. A width of the first chip terminals 310 may be smaller than a width of the outer terminal 160. The first chip terminals 310 may be solder balls that are formed of an alloy containing at least one of tin (Sn), silver (Ag), copper (Cu), nickel (Ni), bismuth (Bi), indium (In), antimony (Sb), or cerium (Ce).

First non-conductive layers 410 may be disposed between the first semiconductor chip 100 and the chip stack (i.e., between the first semiconductor chip 100 and the lowermost one of the lower semiconductor chips 201) and between adjacent ones of the lower semiconductor chips 201 to enclose the first chip terminals 310. Some of the first non-conductive layers 410 may be disposed between the first semiconductor chip 100 and the lowermost one of the lower semiconductor chips 201 to enclose the first chip terminal 310. Others of the first non-conductive layers 410 may be disposed between adjacent ones of the lower semiconductor chips 201 to enclose the first chip terminals 310. The first non-conductive layer 410 may have an extension portion, which is extruded to a region outside a side surface of the lower semiconductor chip 201. The extension portion of the first non-conductive layer 410 may cover a portion of the side surface of the lower semiconductor chip 201 thereon. The first non-conductive layers 410 may be formed of or include an insulating material. For example, the first non-conductive layers 410 may include a non-conductive film (NCF) or a non-conductive paste (NCP). The first non-conductive layers 410 may be formed of or include an insulating polymer. For example, the first non-conductive layers 410 may be formed of or include an epoxy-based material, which does not contain any conductive particle. Since the first non-conductive layer 410 in use does not contain conductive particles, it may be possible to reduce the pitch of the first chip terminals 310, without an electric short issue between adjacent ones of the first chip terminals 310. In addition, since the first non-conductive layers 410 are used as under-fill layers filling a space between the first semiconductor chip 100 and the lowermost one of the lower semiconductor chips 201 and a space between adjacent ones of the lower semiconductor chips 201, it may be possible to improve the mechanical durability of the first chip terminals 310.

The upper semiconductor chip 202 may be disposed on the uppermost one of the lower semiconductor chips 201. A width of the upper semiconductor chip 202 may be smaller than the width of the first semiconductor chip 100 in the horizontal direction. The width of the upper semiconductor chip 202 may be equal to the widths of the lower semiconductor chips 201 in the horizontal direction. Side surfaces of the lower semiconductor chips 201 may be coplanar to a side surface of the upper semiconductor chip 202. For example, the semiconductor chips of the chip stack may be coplanar to each other. A third thickness T3 of the upper semiconductor chip 202 may be equal to the second thickness T2 of the lower semiconductor chip 201 in the vertical direction. The third thickness T3 of the upper semiconductor chip 202 may be smaller than the first thickness T1 of the first semiconductor chip 100 in the vertical direction. The third thickness T3 of the upper semiconductor chip 202 may range from 20 μm to 40 μm. The upper semiconductor chip 202 may have substantially the same structure as the lower semiconductor chips 201. For example, the upper semiconductor chip 202 may include the second circuit layer 210 facing the first semiconductor chip 100, the second protection layer 240 opposite to the second circuit layer 210, the second via 220 extended from the second protection layer 240 toward the second circuit layer 210 to penetrate the upper semiconductor chip 202, the second upper pad 230 in the second protection layer 240, and the second lower pad 250 on the second circuit layer 210. The second circuit layer 210 may include a memory circuit. A width of the second upper pad 230 may be smaller than the first width W1 of the first lower pad 150 in the horizontal direction. The second lower pad 250 of the upper semiconductor chip 202 may have a third width W3 in the horizontal direction. The third width W3 of the second lower pad 250 of the upper semiconductor chip 202 may be smaller than the first width W1 of the first lower pad 150 in the horizontal direction. The third width W3 of the second lower pad 250 of the upper semiconductor chip 202 may be equal to the second width W2 of the second lower pad 250 of the lower semiconductor chips 201 in the horizontal direction.

According to an embodiment, the first thickness T1 of the first semiconductor chip 100 may be greater than the second and third thicknesses T2 and T3 of the lower and upper semiconductor chips 201 and 202 of the chip stack in the vertical direction. Thus, even when many semiconductor chips 201 and 202 are provided in the chip stack, they may be more robustly supported by the first semiconductor chip 100, and the first semiconductor chip 100 may not be damaged in a process of fabricating the semiconductor package (in particular, in a step of mounting the semiconductor chips 201 and 202 on the first semiconductor chip 100). For example, it may be possible to realize a semiconductor package with improved structural stability.

According to an embodiment, the third thickness T3 of the upper semiconductor chip 202, which is the uppermost chip in the chip stack, may not be greater than the second thicknesses T2 of the lower semiconductor chips 201 in the vertical direction, and thus, the chip stack may have a relatively small height. Furthermore, the chip stack in the semiconductor package may be required to have a specific height, and in this case, since the third thickness T3 of the upper semiconductor chip 202 is relatively small, it may be possible to increase the number of the semiconductor chips 201 and 202 provided in the chip stack. For example, it may be possible to realize a semiconductor package with a relatively small size and a relatively high integration density.

According to an embodiment, the upper semiconductor chip 202, which is the uppermost chip in the chip stack, may have the second vias 220 vertically penetrating the upper semiconductor chip 202. Thus, heat, which is generated from the semiconductor chips 201 and 202 in the chip stack, may be more easily exhausted to a region on the chip stack through the upper semiconductor chip 202 and the second vias 220 in the upper semiconductor chip 202. For example, it may be possible to improve the heat-dissipation efficiency of the semiconductor package.

Referring further to FIGS. 1 to 3, the upper semiconductor chip 202 and the uppermost one of the lower semiconductor chips 201 may be connected to each other by a second chip terminal 320. For example, the second chip terminal 320 may be disposed between the second upper pad 230 of the uppermost one of the lower semiconductor chips 201 and the second lower pad 250 of the upper semiconductor chip 202. The second chip terminal 320 may connect the second upper pad 230 to the second lower pad 250. In an embodiment, a plurality of second chip terminals 320 may be provided between the uppermost one of the lower semiconductor chips 201 and the upper semiconductor chip 202. The second chip terminal 320 may electrically connect the uppermost one of the lower semiconductor chips 201 to the upper semiconductor chip 202. A width of the second chip terminals 320 may be smaller than a width of the outer terminal 160 in the horizontal direction. The second chip terminals 320 may be solder balls that are formed of an alloy containing at least one of tin (Sn), silver (Ag), copper (Cu), nickel (Ni), bismuth (Bi), indium (In), antimony (Sb), or cerium (Ce).

A second non-conductive layer 420 may be disposed between the uppermost one of the lower semiconductor chips 201 and the upper semiconductor chip 202 to enclose the second chip terminal 320. The second non-conductive layer 420 may have an extension portion, which is extruded to a region outside the side surface of the upper semiconductor chip 202. The extension portion of the second non-conductive layer 420 may cover a portion of the side surface of the upper semiconductor chip 202 thereon. The second non-conductive layer 420 may include an insulating material. For example, the second non-conductive layer 420 may include a non-conductive film (NCF) or a non-conductive paste (NCP). The second non-conductive layer 420 may include an insulating polymer. For example, the second non-conductive layer 420 may be formed of or include an epoxy-based material, which does not contain any conductive particle. Since the second non-conductive layer 420 in use does not contain conductive particles, it may be possible to reduce the pitch of the second chip terminals 320, without an electric short issue between adjacent ones of the second chip terminals 320. In addition, since the second non-conductive layer 420 is used as an under-fill layer filling a space between the uppermost one of the lower semiconductor chips 201 and the upper semiconductor chip 202, it may be possible to improve the mechanical durability of the second chip terminals 320.

A mold layer 500 may be provided on the first semiconductor chip 100. The mold layer 500 may cover the top surface of the first semiconductor chip 100. A side surface of the mold layer 500 may be coplanar to a side surface of the first semiconductor chip 100. The mold layer 500 may enclose the chip stack. For example, the mold layer 500 may cover the side surfaces of the second semiconductor chips 201 and 202. The mold layer 500 may expose a top surface of the upper semiconductor chip 202. The mold layer 500 may protect the second semiconductor chips 201 and 202. The mold layer 500 may include an insulating material. For example, the mold layer 500 may include an epoxy molding compound (EMC). Unlike the illustrated structure, the mold layer 500 may be formed to cover the second semiconductor chips 201 and 202. For example, the mold layer 500 may cover the top surface of the upper semiconductor chip 202.

In the description of the embodiments to be explained below, an element previously described with reference to FIGS. 1 and 2 may be identified by the same reference number without repeating an overlapping description thereof, for concise description.

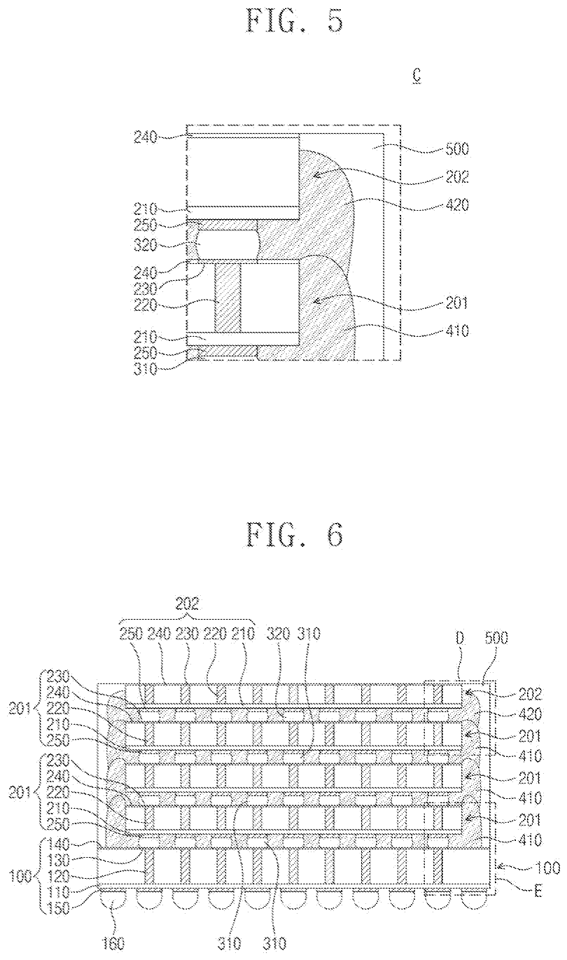

FIG. 4 is a sectional view illustrating a semiconductor package according to an embodiment. FIG. 5 is an enlarged sectional view of a portion ‘C’ of FIG. 4.

Referring to FIGS. 4 and 5, the upper semiconductor chip 202 may be disposed on the uppermost one of the lower semiconductor chips 201. The width of the upper semiconductor chip 202 may be smaller than the width of the first semiconductor chip 100 in the horizontal direction. The width of the upper semiconductor chip 202 may be equal to the widths of the lower semiconductor chips 201 in the horizontal direction. The semiconductor chips of the chip stack may be vertically aligned to each other. The third thickness of the upper semiconductor chip 202 may be equal to the second thickness of the lower semiconductor chip 201 in the vertical direction. The third thickness of the upper semiconductor chip 202 may be smaller than the first thickness of the first semiconductor chip 100 in the vertical direction. The upper semiconductor chip 202 may have a structure that is substantially similar to the lower semiconductor chips 201. For example, the upper semiconductor chip 202 may include the second circuit layer 210 facing the first semiconductor chip 100, the second protection layer 240 opposite to the second circuit layer 210, and the second lower pad 250 on the second circuit layer 210. For example, the upper semiconductor chip 202 may not have the second via 220, which is provided to vertically penetrate the upper semiconductor chip 202, and the second upper pad 230, which is provided in the second protection layer 240, unlike the lower semiconductor chips 201. For example, the upper semiconductor chip 202 may have a relatively simpler structure than the lower semiconductor chips 201.

In an embodiment, it may be possible to realize a semiconductor package with a relatively small size, a relatively high integration density, and a relatively simple structure.

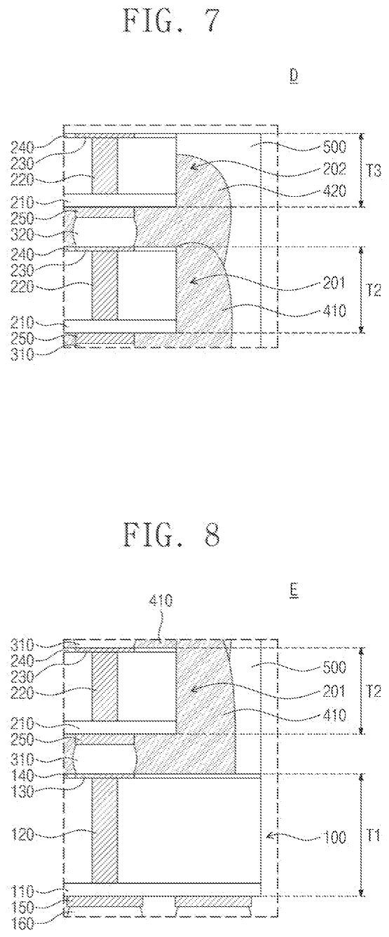

FIG. 6 is a sectional view illustrating a semiconductor package according to an embodiment. FIG. 7 is an enlarged sectional view of a portion ‘D’ of FIG. 6. FIG. 8 is an enlarged sectional view of a portion ‘E’ of FIG. 6.

Referring to FIGS. 6 to 8, the upper semiconductor chip 202 may be disposed on the uppermost one of the lower semiconductor chips 201. The third thickness T3 of the upper semiconductor chip 202 may be smaller than the second thickness T2 of the lower semiconductor chip 201 in the vertical direction. For example, the upper semiconductor chip 202, which is the uppermost chip in the chip stack, may be the thinnest semiconductor chip. The third thickness T3 of the upper semiconductor chip 202 may be smaller than the first thickness T1 of the first semiconductor chip 100 in the vertical direction. The upper semiconductor chip 202 may have substantially the same structure as the lower semiconductor chips 201. For example, the upper semiconductor chip 202 may include the second circuit layer 210 facing the first semiconductor chip 100, the second protection layer 240 opposite to the second circuit layer 210, the second via 220 extended from the second protection layer 240 toward the second circuit layer 210 to penetrate the upper semiconductor chip 202, the second upper pad 230 in the second protection layer 240, and the second lower pad 250 on the second circuit layer 210.

In an embodiment, the third thickness T3 of the upper semiconductor chip 202, which is the uppermost chip in the chip stack, may be smaller than the second thicknesses T2 of the lower semiconductor chips 201 in the vertical direction, and thus, the chip stack may have a relatively small height. Furthermore, since the third thickness T3 of the upper semiconductor chip 202 is relatively small, it may be possible to increase the number of the semiconductor chips 201 and 202 provided in the chip stack. For example, it may be possible to realize a semiconductor package with a relatively small size and a relatively high integration density.

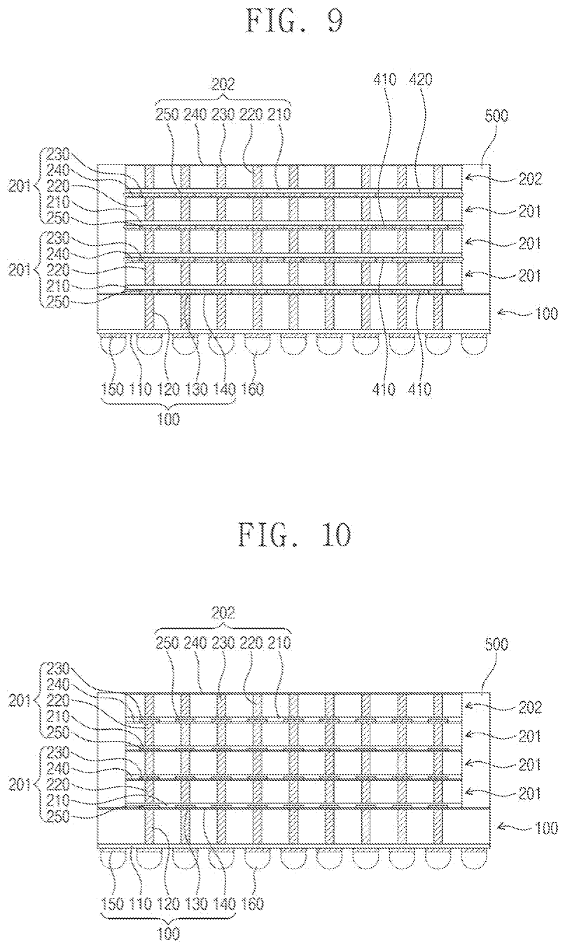

FIG. 9 is a sectional view illustrating a semiconductor package according to an embodiment.

FIGS. 1 to 8 illustrate examples, in which the lower semiconductor chips 201 and the upper semiconductor chip 202 are mounted on the first semiconductor chip 100 and the lower semiconductor chips 201 using the chip terminals 310 and 320, but embodiments are not limited thereto.

Referring to FIG. 9, adjacent ones of the lower semiconductor chips 201 may be directly connected to each other. For example, the lower semiconductor chips 201, which are vertically adjacent to each other, may be directly connected to each other.

The second upper pad 230 and the second lower pad 250, which are respectively included in the adjacent ones of the lower semiconductor chips 201, may be in direct contact with each other. Here, the second upper pad 230 and the second lower pad 250 may form an inter-metal hybrid bonding structure. In the present specification, the hybrid bonding structure may be a bonding structure which is formed by two materials, which are of the same type and are fused at an interface therebetween. For example, the second upper pad 230 and the second lower pad 250, which are bonded to each other, may have a continuous structure, and there may be no visible interface between the second upper pad 230 and the second lower pad 250. For example, the second upper pad 230 and the second lower pad 250 may be formed of the same material, and thus, there may be no interface between the second upper pad 230 and the second lower pad 250. For example, the second upper pad 230 and the second lower pad 250 may be provided as a single element. For example, the second upper pad 230 and the second lower pad 250 may be coupled to each other to form a single object.

The first non-conductive layers 410 may be disposed between the lower semiconductor chips 201, which are adjacent to each other. The first non-conductive layers 410 between adjacent ones of the lower semiconductor chips 201 may enclose the second upper pad 230 and the second lower pad 250.

The upper semiconductor chip 202 and the uppermost one of the lower semiconductor chips 201 may be directly connected to each other.

The second upper pad 230 of the uppermost one of the lower semiconductor chips 201 may be in direct contact with the second lower pad 250 of the upper semiconductor chip 202. Here, the second upper pad 230 and the second lower pad 250 may form an inter-metal hybrid bonding structure. For example, the second upper pad 230 and the second lower pad 250, which are bonded to each other, may have a continuous structure, and there may be no visible interface between the second upper pad 230 and the second lower pad 250. For example, the second upper pad 230 and the second lower pad 250 may be formed of the same material, and thus, there may be no interface between the second upper pad 230 and the second lower pad 250. In other words, the second upper pad 230 and the second lower pad 250 may be provided as a single element. For example, the second upper pad 230 and the second lower pad 250 may be coupled to each other to form a single object.

The second non-conductive layer 420 may be disposed between the uppermost one of the lower semiconductor chips 201 and the upper semiconductor chip 202. The second non-conductive layer 420 may be disposed between the uppermost one of the lower semiconductor chips 201 and the upper semiconductor chip 202 to enclose the second upper pad 230 and the second lower pad 250.

In an embodiment, the pads 230 and 250 of the second semiconductor chips 201 and 202 may be directly connected to each other. For example, the pads 230 and 250 of the second semiconductor chips 201 and 202 may be connected to each other without additional chip terminals, and a distance between the second semiconductor chips 201 and 202 may be relatively small. For example, it may be possible to realize a semiconductor package with a relatively small size.

The first semiconductor chip 100 and the chip stack may be directly connected to each other. For example, the first semiconductor chip 100 may be directly connected to the lowermost one of the lower semiconductor chips 201 of the chip stack.

The first upper pad 130 of the first semiconductor chip 100 may be in direct contact with the second lower pad 250 of the lowermost one of the lower semiconductor chips 201. Here, the first upper pad 130 and the second lower pad 250 may form an inter-metal hybrid bonding structure. For example, the first upper pad 130 and the second lower pad 250, which are bonded to each other, may have a continuous structure, and there may be no visible interface between the first upper pad 130 and the second lower pad 250. For example, the first upper pad 130 and the second lower pad 250 may be formed of the same material, and thus, there may be no interface between the first upper pad 130 and the second lower pad 250. For example, the first upper pad 130 and the second lower pad 250 may be provided as a single element. For example, the first upper pad 130 and the second lower pad 250 may be coupled to each other to form a single object.

A portion of the first non-conductive layer 410 may be disposed between the first semiconductor chip 100 and the chip stack. The portion of the first non-conductive layer 410 may be disposed between the first semiconductor chip 100 and the lowermost one of the lower semiconductor chips 201 to enclose the first upper pad 130 and the second lower pad 250.

FIG. 9 illustrates an example, in which the chip stack is directly connected to the first semiconductor chip 100, but embodiments are not limited thereto. The chip stack may be mounted on the first semiconductor chip 100 using additional connection terminals. For example, while the semiconductor chips 201 and 202 of the chip stack are directly connected to each other, the lowermost one of the lower semiconductor chips 201 may be coupled to the first upper pad 130 of the first semiconductor chip 100 using a chip connection terminal provided on the second lower pad 250.

FIG. 10 is a sectional view illustrating a semiconductor package according to an embodiment.

Referring to FIG. 10, each of the lower semiconductor chips 201 may include the second circuit layer 210, the second via 220, the second upper pad 230, the second protection layer 240, and the second lower pad 250.

The top surface of the second protection layer 240 and the top surface of the second upper pad 230 may be substantially flat and may be substantially coplanar with each other.

The second lower pads 250 may be disposed on bottom surfaces of the lower semiconductor chips 201. For example, the second lower pad 250 may be disposed in the second circuit layer 210. The bottom surface of the second lower pad 250 and the bottom surface of the second circuit layer 210 may be substantially flat and may be substantially coplanar with each other. The second lower pad 250 may be electrically connected to the second circuit layer 210.

The lower semiconductor chips 201, which are adjacent to each other, may be in direct contact with each other. In an embodiment, a top surface of the lower semiconductor chip 201 may be in full contact with the bottom surface of another lower semiconductor chip 201 thereon.

On an interface between the lower semiconductor chips 201, the second protection layer 240 of the lower semiconductor chip 201 may be bonded to an insulating pattern of the second circuit layer 210 of another lower semiconductor chip 201 thereon. Here, the second protection layer 240 and the insulating pattern of the second circuit layer 210 may form a hybrid bonding structure of oxide, nitride, or oxynitride. For example, the second protection layer 240 and the insulating pattern of the second circuit layer 210 may be formed of the same material, and thus, there may be no interface between the second protection layer 240 and the insulating pattern of the second circuit layer 210. For example, the second protection layer 240 and the insulating pattern of the second circuit layer 210 may be coupled to each other to form a single object. However, embodiments are not limited thereto. The second protection layer 240 and the insulating pattern of the second circuit layer 210 may be formed of different materials from each other and may not have a continuous structure, and thus, there may be a visible interface between the second protection layer 240 and the insulating pattern of the second circuit layer 210.

On the interface between the lower semiconductor chips 201, the second upper pad 230 and the second lower pad 250, which are respectively included in the adjacent ones of the lower semiconductor chips 201, may be in direct contact with each other. Here, the second upper pad 230 and the second lower pad 250 may form an inter-metal hybrid bonding structure. For example, the second upper pad 230 and the second lower pad 250, which are bonded to each other, may have a continuous structure, and there may be no visible interface between the second upper pad 230 and the second lower pad 250.

The upper semiconductor chip 202 may include the second circuit layer 210, the second via 220, the second upper pad 230, the second protection layer 240, and the second lower pad 250.

The second lower pad 250 may be disposed in the second circuit layer 210. The bottom surface of the second lower pad 250 and the bottom surface of the second circuit layer 210 may be substantially flat and may be substantially coplanar with each other.

The uppermost one of the lower semiconductor chips 201 may be in direct contact with the upper semiconductor chips 202. In an embodiment, a top surface of the uppermost one of the lower semiconductor chips 201 may be entirely in contact with a bottom surface of the upper semiconductor chip 202.

On an interface between the uppermost one of the lower semiconductor chips 201 and the upper semiconductor chip 202, the second protection layer 240 of the uppermost one of the lower semiconductor chips 201 may be bonded to the insulating pattern of the second circuit layer 210 of the upper semiconductor chip 202. Here, the second protection layer 240 and the insulating pattern of the second circuit layer 210 may form a hybrid bonding structure of oxide, nitride, or oxynitride. For example, the second protection layer 240 and the insulating pattern of the second circuit layer 210 may be formed of the same material, and thus, there may be no interface between the second protection layer 240 and the insulating pattern of the second circuit layer 210. For example, the second protection layer 240 and the insulating pattern of the second circuit layer 210 may be coupled to each other to form a single object. However, embodiments are not limited thereto. The second protection layer 240 and the insulating pattern of the second circuit layer 210 may be formed of different materials from each other and may not have a continuous structure, and thus, there may be a visible interface between the second protection layer 240 and the insulating pattern of the second circuit layer 210.

On the interface between the uppermost one of the lower semiconductor chips 201 and the upper semiconductor chip 202, the second upper pad 230 of the uppermost one of the lower semiconductor chips 201 may be in direct contact with the second lower pad 250 of the upper semiconductor chip 202. Here, the second upper pad 230 and the second lower pad 250 may form an inter-metal hybrid bonding structure. For example, the second upper pad 230 and the second lower pad 250, which are bonded to each other, may have a continuous structure, and there may be no visible interface between the second upper pad 230 and the second lower pad 250.

According to an embodiment, the second semiconductor chips 201 and 202 may be entirely in contact with each other. Thus, a distance between the second semiconductor chips 201 and 202 may be zero and it may be possible to realize a semiconductor package with a relatively small size.

The first semiconductor chip 100 and the chip stack may be in direct contact with each other. For example, the top surface of the first semiconductor chip 100 may be entirely in contact with the bottom surface of the lowermost one of the lower semiconductor chips 201 of the chip stack.

On the interface between the first semiconductor chip 100 and the lowermost one of the lower semiconductor chips 201, the first protection layer 140 of the first semiconductor chip 100 may be bonded to the insulating pattern of the second circuit layer 210 of the lowermost one of the lower semiconductor chips 201. Here, the first protection layer 140 and the insulating pattern of the second circuit layer 210 may form a hybrid bonding structure of oxide, nitride, or oxynitride. For example, the first protection layer 140 and the insulating pattern of the second circuit layer 210 may be formed of the same material, and thus, there may be no interface between the first protection layer 140 and the insulating pattern of the second circuit layer 210. For example, the first protection layer 140 and the insulating pattern of the second circuit layer 210 may be coupled to each other to form a single object. However, embodiments are not limited thereto. The first protection layer 140 and the insulating pattern of the second circuit layer 210 may be formed of different materials from each other and may not have a continuous structure, and thus, there may be a visible interface between the first protection layer 140 and the insulating pattern of the second circuit layer 210.

On the interface between the first semiconductor chip 100 and the lowermost one of the lower semiconductor chips 201, the first upper pad 130 of the first semiconductor chip 100 may be in direct contact with the second lower pad 250 of the lowermost one of the lower semiconductor chips 201. Here, the first upper pad 130 and the second lower pad 250 may form an inter-metal hybrid bonding structure. For example, the first upper pad 130 and the second lower pad 250, which are bonded to each other, may have a continuous structure, and there may be no visible interface between the first upper pad 130 and the second lower pad 250.

FIG. 10 illustrates an example, in which the chip stack is in direct contact with the first semiconductor chip 100, but embodiments are not limited thereto. The chip stack may be mounted on the first semiconductor chip 100 using additional connection terminals. For example, while the semiconductor chips 201 and 202 of the chip stack are directly connected to each other, the lowermost one of the lower semiconductor chips 201 may be coupled to the first upper pad 130 of the first semiconductor chip 100 using a chip connection terminal provided on the second lower pad 250.

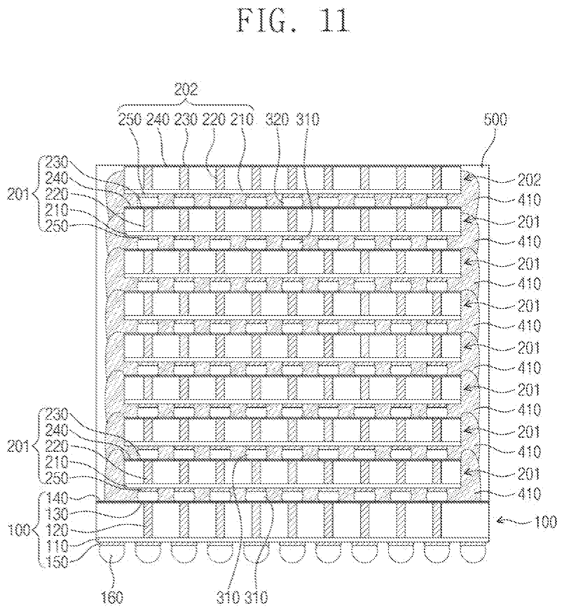

FIG. 11 is a sectional view illustrating a semiconductor package according to an embodiment.

FIGS. 1 to 10 illustrate the embodiments, in which three lower semiconductor chips 201 are interposed between the first semiconductor chip 100 and the upper semiconductor chip 202 or the chip stack has four semiconductor chips, but the inventive concept is not limited to these embodiments. As shown in FIG. 11, seven lower semiconductor chips 201 may be interposed between the first semiconductor chip 100 and the upper semiconductor chip 202. According to embodiments, one, two, four, or more lower semiconductor chips 201 may be interposed between the first semiconductor chip 100 and the upper semiconductor chip 202. For example, 3 to 15 lower semiconductor chips 201 may be provided between the first semiconductor chip 100 and the upper semiconductor chip 202, and the chip stack may have 4 to 16 semiconductor chips.

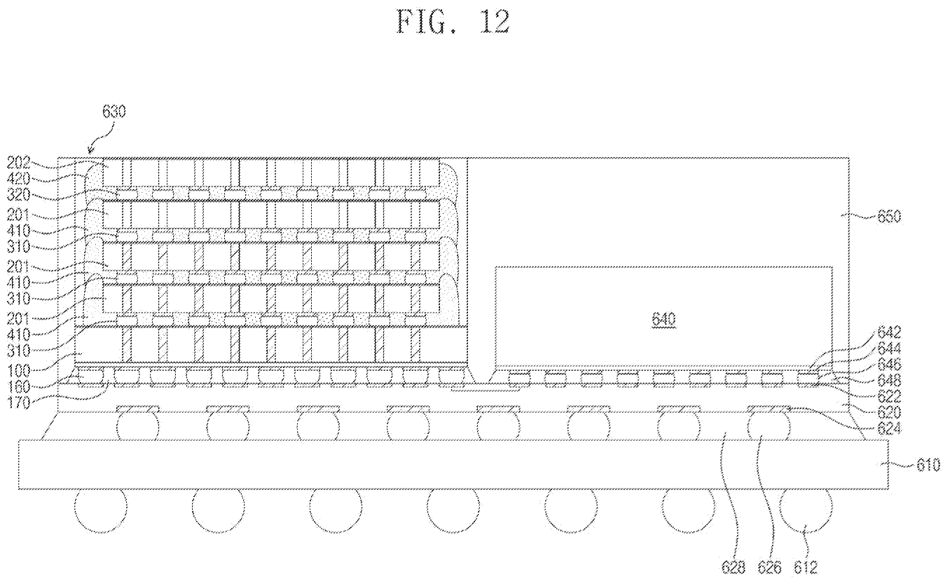

FIG. 12 is a sectional view illustrating a semiconductor module according to an embodiment.

Referring to FIG. 12, a semiconductor module may be a memory module and may include a module substrate 610, a chip stack package 630 and a graphic processing unit (GPU) 640, which are mounted on the module substrate 610, and an outer mold layer 650, which is provided to cover the chip stack package 630 and the graphic processing unit 640. The semiconductor module may further include an interposer 620 provided on the module substrate 610.

The module substrate 610 may be provided. The module substrate 610 may include a printed circuit board (PCB) having signal patterns, which are formed on a top surface of the module substrate 610.

Module terminals 612 may be disposed below the module substrate 610. The module substrate 610 may include solder balls or solder bumps, and the semiconductor module may be classified into a ball grid array (BGA) type, a fine ball-grid array (FBGA) type, or a land grid array (LGA) type, depending on the type and structure of the module substrate 610.

The interposer 620 may be provided on the module substrate 610. The interposer 620 may include first substrate pads 622 and second substrate pads 624, which are respectively placed on top and bottom surfaces of the interposer 620. The interposer 620 may be configured to provide a redistribution structure for the chip stack package 630 and the graphic processing unit 640. The interposer 620 may be mounted on the module substrate 610 in a flip chip manner. For example, the interposer 620 may be mounted on the module substrate 610 using substrate terminals 626, which are provided on the second substrate pads 624. The substrate terminals 626 may include solder balls or solder bumps. A first under-fill layer 628 may be provided between the module substrate 610 and the interposer 620.

The chip stack package 630 may be disposed on the interposer 620. The chip stack package 630 may have the same or similar structure as the semiconductor package described with reference to FIGS. 1 to 11.

The chip stack package 630 may be mounted on the interposer 620. For example, the chip stack package 630 may be coupled to the first substrate pads 622 of the interposer 620 through the outer terminals 160 of the first semiconductor chip 100. A second under-fill layer 170 may be provided between the chip stack package 630 and the interposer 620. The second under-fill layer 170 may be provided to fill a space between the interposer 620 and the first semiconductor chip 100 and enclose the outer terminals 160 of the first semiconductor chip 100.

The graphic processing unit 640 may be disposed on the interposer 620. The graphic processing unit 640 may be disposed to be spaced apart from the chip stack package 630. The graphic processing unit 640 may be thicker than the semiconductor chips 100, 201, and 202 of the chip stack package 630 in the vertical direction. A chip circuit layer 642 may be provided on a bottom surface of the graphic processing unit 640. The chip circuit layer 642 of the graphic processing unit 640 may include a logic circuit. For example, the graphic processing unit 640 may be a logic chip. Chip pads 644 may be provided on the bottom surface of the graphic processing unit 640. The chip pads 644 may be disposed on a bottom surface of the chip circuit layer 642 and may be electrically connected to the chip circuit layer 642. Bumps 646 may be provided on the chip pads 644. For example, the graphic processing unit 640 may be coupled to the first substrate pads 622 of the interposer 620 through the bumps 646. A third under-fill layer 648 may be provided between the interposer 620 the graphic processing unit 640. The third under-fill layer 648 may be provided to fill a space between the interposer 620 and the graphic processing unit 640 and enclose the bumps 646.

The outer mold layer 650 may be provided on the interposer 620. The outer mold layer 650 may cover the top surface of the interposer 620. The outer mold layer 650 may enclose the chip stack package 630 and the graphic processing unit 640. A top surface of the outer mold layer 650 may be located at the same level as a top surface of the chip stack package 630 in the vertical direction. The outer mold layer 650 may include an insulating material. For example, the outer mold layer 650 may include an epoxy molding compound (EMC).

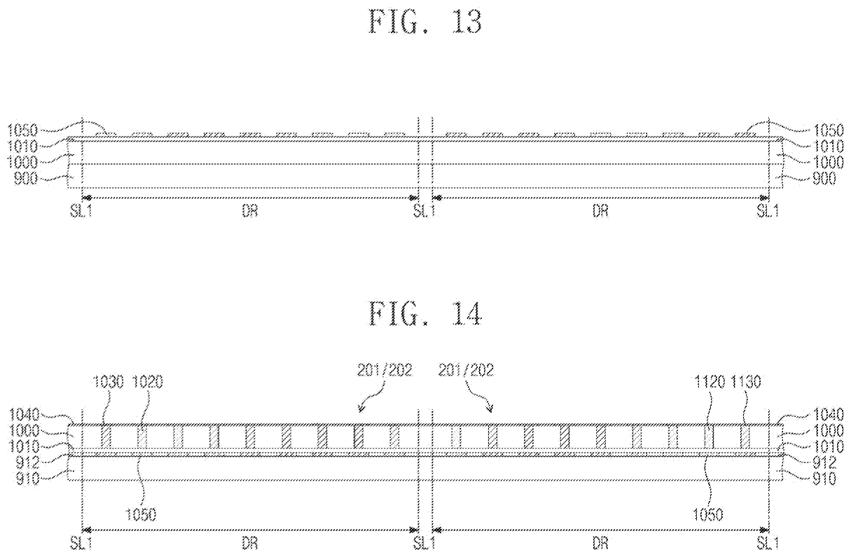

FIGS. 13 to 20 are sectional views illustrating a method of fabricating a semiconductor package, according to an embodiment of the inventive concept.

Referring to FIG. 13, a first wafer 1000 may be provided. The first wafer 1000 may have a top surface and a bottom surface, which are opposite to each other. For example, the first wafer 1000 may be a silicon wafer or a non-silicon semiconductor wafer. The first wafer 1000 may have device regions DR, which are spaced apart from each other. The device regions DR may be divided by a first sawing line SL1, on which a sawing process will be performed. Each of the device regions DR may be a region, in which one second semiconductor chip 201 or 202 (e.g., see FIG. 16) will be formed.

The first wafer 1000 may be provided on a first carrier substrate 900. The first carrier substrate 900 may be an insulating substrate, which includes glass or polymer, or a conductive substrate, which includes a metallic material. An adhesive member may be provided on a top surface of the first carrier substrate 900. In an embodiment, the adhesive member may include an adhesive tape.

A second circuit layer 1010 may be formed on the first wafer 1000. The second circuit layer 1010 may include an electronic element (e.g., a transistor). For example, the second circuit layer 1010 may be formed using a typical process, such as a doping process, a deposition process, a patterning process. For example, a top surface of the first wafer 1000, on which the second circuit layer 1010 is formed, may be an active surface of the first wafer 1000.

Second lower pads 1050 may be formed on the second circuit layer 1010. The second lower pads 1050 may be electrically connected to the second circuit layer 1010.

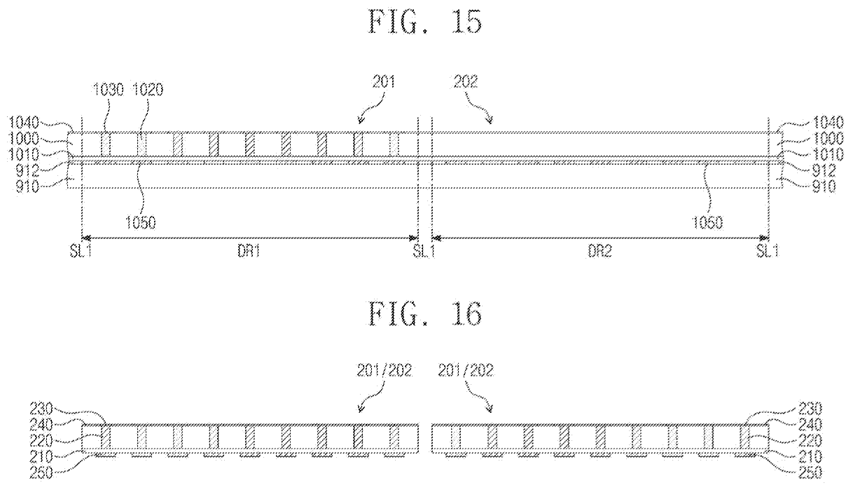

Referring to FIG. 14, the first carrier substrate 900 may be removed. Accordingly, an inactive surface of the first wafer 1000 may be exposed.

The first wafer 1000 may be provided on a second carrier substrate 910. The second carrier substrate 910 may be an insulating substrate, which includes glass or polymer, or a conductive substrate, which includes a metallic material. An adhesive member 912 may be provided on a top surface of the second carrier substrate 910. As an example, the adhesive member 912 may include an adhesive tape. The first wafer 1000 may be attached to the second carrier substrate 910 such that the second circuit layer 1010 faces the second carrier substrate 910. If necessary, a thinning process may be performed on the inactive surface of the first wafer 1000.

Second vias 1020 may be formed in the first wafer 1000. For example, the second vias 1020 may be formed by forming penetration holes to vertically penetrate the first wafer 1000 and filling the penetration holes with a conductive material.

Second upper pads 1030 may be formed on the first wafer 1000. For example, the second upper pads 1030 may be formed by forming a conductive layer on the inactive surface of the first wafer 1000 and patterning the conductive layer. The second upper pads 1030 may be formed on the second vias 1020 and may be coupled to the second vias 1020.

A second protection layer 1040 may be formed on the first wafer 1000. The second protection layer 1040 may enclose the second upper pads 1030.

As described above, the second semiconductor chips 201 and 202 may be formed on the device regions DR of the first wafer 1000. In the embodiment of FIG. 14, the lower and upper semiconductor chips 201 and 202, which are included in the second semiconductor chips 201 and 202, are illustrated to have the same elements, but embodiments are not limited thereto.

In another embodiment, the first carrier substrate 900 may be removed, as shown in FIG. 15. The first wafer 1000 may be provided on the second carrier substrate 910. The second vias 1020, the second upper pads 1030, and the second protection layer 1040 may be formed on the first wafer 1000. Here, the second vias 1020, the second upper pads 1030, and the second protection layer 1040 may be formed only on a device region DR1, which is one of the device regions DR, not on another device region DR2. The lower semiconductor chip 201 may be formed on the device region DR1 provided with the second vias 1020, the second upper pads 1030, and the second protection layer 1040, and the upper semiconductor chip 202 may be formed on the device region DR2, in which the second vias 1020, the second upper pads 1030, and the second protection layer 1040 are not formed. The following description will be given based on the embodiment of FIG. 14.

Referring to FIG. 16, a singulation process may be performed on the first wafer 1000 to separate the second semiconductor chips 201 and 202 from each other. For example, a sawing process may be performed along the first sawing line SL1. Some of the second semiconductor chips 201 and 202, which are separated from each other, may be the lower semiconductor chips 201, and the others may be the upper semiconductor chips 202. Since the lower and upper semiconductor chips 201 and 202 are formed using the same wafer (i.e., the first wafer 1000), the lower and upper semiconductor chips 201 and 202 may have the same thickness. The second circuit layer 1010 of the first wafer 1000 may be divided into the second circuit layers 210 of the second semiconductor chips 201 and 202. The second protection layer 1040 of the first wafer 1000 may be divided into the second protection layers 240 of the second semiconductor chips 201 and 202. The second lower pads 1050, the second vias 1020, and the second upper pads 1030 of the first wafer 1000 may correspond to the second lower pads 250, the second vias 220, and the second upper pads 230 of the second semiconductor chips 201 and 202, respectively.

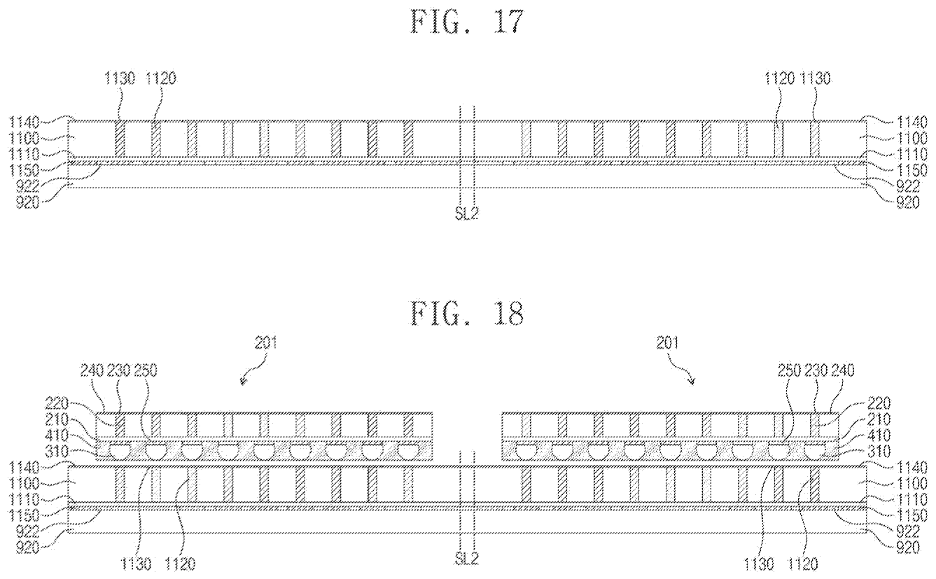

Referring to FIG. 17, a second wafer 1100 may be provided. The second wafer 1100 may have a top surface and a bottom surface, which are opposite to each other. For example, the second wafer 1100 may be a silicon wafer or a non-silicon semiconductor wafer. In an embodiment, not a wafer but a printed circuit board (PCB) may be provided. A thickness of the second wafer 1100 may be greater than a thickness of the first wafer 1000. The second wafer 1100 may include a first circuit layer 1110, a first protection layer 1140 opposite to the first circuit layer 1110, first vias 1120, which are extended from the first protection layer 1140 toward the first circuit layer 1110 to penetrate the second wafer 1100, first upper pads 1130 in the first protection layer 1140, and a first lower pad 1150 on the first circuit layer 1110.

The second wafer 1100 may be provided on a third carrier substrate 920. The third carrier substrate 920 may be an insulating substrate, which includes glass or polymer, or a conductive substrate, which includes a metallic material. An adhesive member 922 may be provided on a top surface of the third carrier substrate 920. As an example, the adhesive member 922 may include an adhesive tape. The second wafer 1100 may be attached to the third carrier substrate 920 such that the first circuit layer 1110 faces the third carrier substrate 920.

Referring to FIG. 18, a plurality of lower semiconductor chips 201 may be provided on the second wafer 1100. Each of the lower semiconductor chips 201 may be one of the semiconductor chips, which are fabricated by the method described with reference to FIGS. 13 to 16. The first chip terminals 310 and the first non-conductive layers 410 enclosing them may be provided on the bottom surfaces of the lower semiconductor chips 201. For example, the first non-conductive layers 410 may include a non-conductive film (NCF) or a non-conductive paste (NCP). In the case where the first non-conductive layers 410 are the non-conductive paste, the first non-conductive layers 410 may be formed by coating a liquid non-conductive paste on the lower semiconductor chips 201 through a dispensing process. In the case where the first non-conductive layers 410 are the non-conductive film, the first non-conductive layers 410 may be formed by attaching the non-conductive films to the lower semiconductor chips 201. In other words, the first non-conductive layers 410 may be provided on the second wafer 1100, and the lower semiconductor chips 201 may be provided on the first non-conductive layers 410.

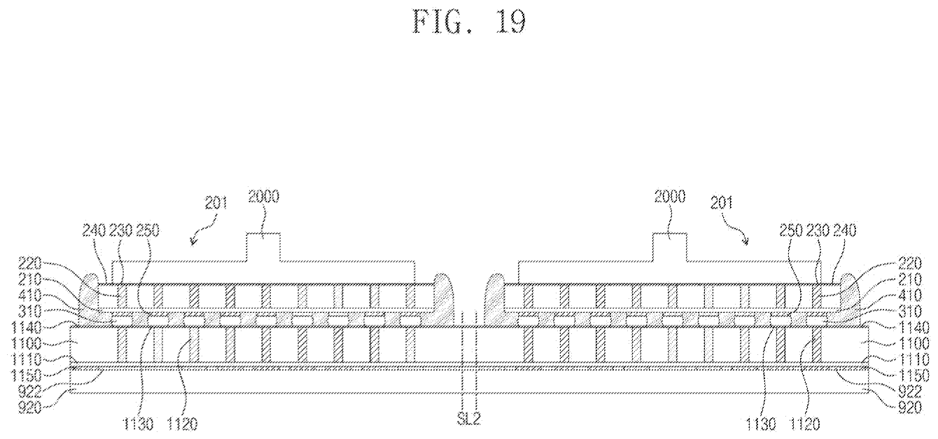

Referring to FIG. 19, the lower semiconductor chips 201 may be bonded to the second wafer 1100 through a thermocompression bonding process. The first chip terminals 310 may electrically connect the second wafer 1100 to the lower semiconductor chips 201. In an embodiment, a width of a bonding tool 2000, which is used in the bonding process, may be smaller than a width of the lower semiconductor chip 201 in the horizontal direction. In the case where the lower semiconductor chips 201 are compressed toward the second wafer 1100, the first non-conductive layers 410 may be extruded to a region outside the side surfaces of the lower semiconductor chips 201. The extruded portion of the first non-conductive layer 410 may form an extension portion. Here, the extension portion may be extended to the side surface of the lower semiconductor chip 201 to cover at least a portion of the side surface of the lower semiconductor chip 201. A thickness of the extension portion may be greater than a distance between the second wafer 1100 and the lower semiconductor chips 201 in the vertical direction.

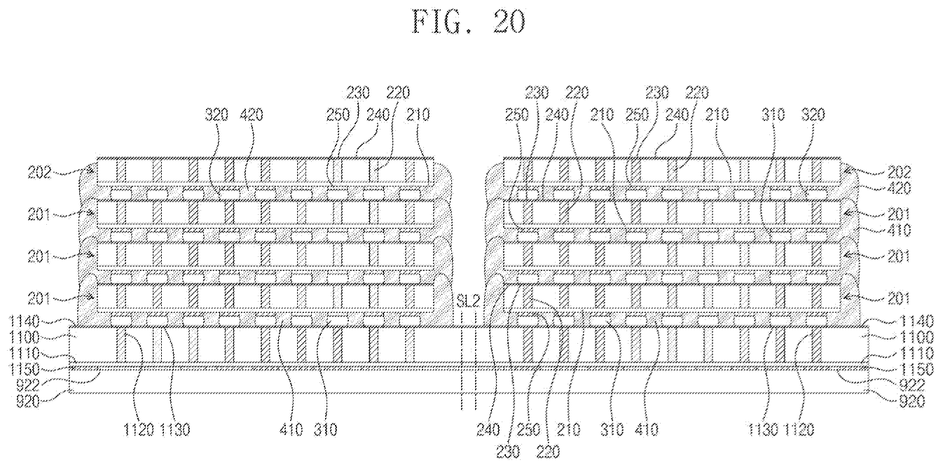

Referring to FIG. 20, the process steps described with reference to FIGS. 18 and 19 may be repeated to stack a plurality of lower semiconductor chips 201 on the second wafer 1100. Other lower semiconductor chips 201 may be disposed on and bonded to the lower semiconductor chips 201, which are disposed on the second wafer 1100. The first chip terminals 310 may electrically connect the lower semiconductor chips 201 to each other.

Next, the upper semiconductor chips 202 may be disposed on the lower semiconductor chips 201. Each of the upper semiconductor chips 202 may be one of the semiconductor chips, which are fabricated by the method described with reference to FIGS. 13 to 16. The process of stacking the upper semiconductor chips 202 may be the same as or similar to the process described with reference to FIGS. 18 and 19. For example, the second chip terminals 320 and the second non-conductive layer 420 enclosing them may be provided on the bottom surfaces of the upper semiconductor chips 202. In the case where the second non-conductive layer 420 is a non-conductive paste, the second non-conductive layer 420 may be formed by coating a liquid non-conductive paste on the upper semiconductor chips 202 through a dispensing process. In the case where the second non-conductive layer 420 is a non-conductive film, the second non-conductive layer 420 may be formed by attaching the non-conductive film to the upper semiconductor chips 202. For example, the second non-conductive layer 420 may be provided on the uppermost one of the lower semiconductor chips 201, and the upper semiconductor chips 202 may be provided on the second non-conductive layer 420.

The upper semiconductor chips 202 may be bonded to the uppermost one of the lower semiconductor chips 201 through a thermocompression bonding process. The second chip terminals 320 may electrically connect the uppermost one of the lower semiconductor chips 201 to the upper semiconductor chips 202. As described above, the lower semiconductor chips 201 and the upper semiconductor chips 202 may be sequentially disposed on the second wafer 1100. The lower and upper semiconductor chips 201 and 202 may constitute chip stacks.

Referring to FIGS. 20 and 1, the mold layer 500 may be formed on the second wafer 1100. The mold layer 500 may cover the chip stacks. The mold layer 500 may enclose the lower semiconductor chips 201, the upper semiconductor chips 202, and non-conductive layers 410 and 420 on the second wafer 1100. For example, the mold layer 500 may be formed by forming an insulating layer on the second wafer 1100 to cover the chip stacks and curing the insulating layer. After the formation of the mold layer 500, a planarization process may be performed on the mold layer 500 to expose the top surfaces of the upper semiconductor chips 202, if necessary.

Next, a singulation process may be performed on the mold layer 500 and the second wafer 1100 to form semiconductor packages, which are separated from each other. For example, a sawing process may be performed along a second sawing line SL2. The sawing process may be performed to cut the mold layer 500 and the second wafer 1100 between the chip stacks.

In a semiconductor package according to an embodiment, a thickness of a base substrate may be greater than thicknesses of semiconductor chips of a chip stack in the vertical direction. Thus, even when many semiconductor chips are provided in the chip stack, they may be more robustly supported by the base substrate, and the base substrate may not be damaged in a process of fabricating the semiconductor package (in particular, in a step of mounting the semiconductor chips on the base substrate). It may be possible to realize a semiconductor package with improved structural stability.

Furthermore, the uppermost semiconductor chip of the chip stack may not be thicker than the remaining ones of the semiconductor chips in the vertical direction, and thus, a height of the chip stack may be reduced. The chip stack in the semiconductor package may be required to have a specific height, and in this case, due to the relatively small thickness of the uppermost semiconductor chip, it may be possible to increase the number of the semiconductor chips provided in the chip stack. It may be possible to realize a semiconductor package with a relatively small size and a relatively high integration density.

In an embodiment, the uppermost semiconductor chip of the chip stack may have vias, which are provided to vertically penetrate the same. In this case, heat, which is generated from the semiconductor chips in the chip stack, may be easily exhausted to a region on the chip stack through the uppermost semiconductor chip and the vias therein. That is, it may be possible to improve the heat-dissipation efficiency of the semiconductor package.

In an embodiment, it may be possible to realize a semiconductor package with a relatively small size, a relatively high integration density, and a relatively simple structure.

While example embodiments have been described with reference to the figures, it will be understood by those of ordinary skill in the art that various changes in form and details may be made therein without departing from the spirit and scope as defined by the following claims and their equivalents.

What is claimed is:

1. A semiconductor package, comprising:
a semiconductor substrate comprising a plurality of first vias;
a chip stack on the semiconductor substrate, the chip stack comprising first semiconductor chips on the semiconductor substrate, and a second semiconductor chip on an uppermost first semiconductor chip of the first semiconductor chips; and
a mold layer on the semiconductor substrate and a portion of the chip stack, and exposing a top surface of the chip stack,
wherein a first thickness of the semiconductor substrate is greater than a second thickness of each of the first semiconductor chips,
wherein a third thickness of the second semiconductor chip is less than or equal to the second thickness of each of the first semiconductor chips,
wherein the semiconductor substrate further comprises lower substrate pads on a bottom surface of the semiconductor substrate,
wherein each of the first semiconductor chips comprises lower chip pads on a bottom surface of each of the first semiconductor chips, and
wherein a first width of each of the lower substrate pads is greater than a second width of each of the lower chip pads.

2. The semiconductor package of claim 1, wherein the third thickness of the second semiconductor chip is equal to the second thickness of each of the first semiconductor chips.

3. The semiconductor package of claim 2, wherein the second semiconductor chip comprises a chip, a type of the chip being same as a type of each of the first semiconductor chips.

4. The semiconductor package of claim 3, wherein the second semiconductor chip comprises second vias vertically penetrating the second semiconductor chip.

5. The semiconductor package of claim 2, wherein the second semiconductor chip comprises a chip, a type of the chip being different from a type of each of the first semiconductor chips,
wherein each of the first semiconductor chips comprises third vias vertically penetrating each of the first semiconductor chips.

6. The semiconductor package of claim 1, wherein the first thickness of the semiconductor substrate ranges from 30 μm to 60 μm, and
wherein the second thickness of each of the first semiconductor chips and the third thickness of the second semiconductor chip range from 20 μm to 40 μm.

7. The semiconductor package of claim 1, wherein each of the first semiconductor chips further comprises upper chip pads on a top surface of each of the first semiconductor chips, and
wherein the lower chip pads and the upper chip pads are respectively in direct contact with each other between adjacent first semiconductor chips of the first semiconductor chips.

8. The semiconductor package of claim 1, wherein first chip terminals are between a first semiconductor chips and the semiconductor substrate and between adjacent first semiconductor chips of the first semiconductor chips,
wherein second chip terminals are between the second semiconductor chip and the uppermost first semiconductor chip of the first semiconductor chips, and
wherein non-conductive layers fill spaces between the semiconductor substrate and the lowermost first semiconductor chip of the first semiconductor chips, between adjacent first semiconductor chips of the first semiconductor chips, and between the uppermost first semiconductor chip of the first semiconductor chip and the second semiconductor chip.

9. The semiconductor package of claim 1, wherein a width of the semiconductor substrate is greater than a width of the chip stack in a horizontal direction.

10. The semiconductor package of claim 1, wherein the semiconductor substrate is a silicon wafer, and
wherein each of the first semiconductor chips is a memory chip.

11. The semiconductor package of claim 1, wherein a number of the first semiconductor chips included in the chip stack ranges from 3 to 15.

12. A semiconductor package, comprising:
a semiconductor substrate comprising a plurality of first vias:
semiconductor chips on the semiconductor substrate, each of the semiconductor chips comprising second vias vertically penetrating the semiconductor chips; and
a mold layer on the semiconductor substrate and the semiconductor chips, and exposing a top surface of an uppermost semiconductor chip of the semiconductor chips,
wherein a first width of the semiconductor substrate is greater than a second width of the chip stack in a horizontal direction,
wherein the semiconductor substrate has a first thickness in a vertical direction,
wherein the semiconductor chips have second thicknesses, which are equal to each other, in the vertical direction, and
wherein the first thickness is greater than the second thicknesses.

13. The semiconductor package of claim 12, wherein the first thickness of the semiconductor substrate ranges from 30 μm to 60 μm, and
wherein the second thicknesses of each of the semiconductor chips ranges from 20 μm to 40 μm.

14. The semiconductor package of claim 12, wherein the semiconductor substrate is a silicon wafer, and
wherein each of the semiconductor chips is a memory chip.

15. The semiconductor package of claim 12, wherein each of the semiconductor chips comprises:
upper chip pads on a top surface of each of the semiconductor chips;
lower chip pads on a bottom surface of each of the semiconductor chips; and
wherein the second vias vertically penetrate the semiconductor chips and vertically connect the upper chip pads to the lower chip pads, and
wherein a lower chip pads and upper chip pads are in direct contact with each other between adjacent semiconductor chips of the semiconductor chips.

16. The semiconductor package of claim 12, wherein chip terminals are between a semiconductor chip of the semiconductor chips and the semiconductor substrate or adjacent semiconductor chips of the semiconductor chips,
wherein the semiconductor substrate further comprises outer terminals on a bottom surface of the semiconductor substrate,
wherein non-conductive layers fill a space between the semiconductor substrate and the lowermost one of the semiconductor chips and spaces between the semiconductor chips, and
wherein a width of each of the outer terminals is greater than a width of each of the chip terminals.

17. The semiconductor package of claim 12, wherein the semiconductor substrate further comprises lower substrate pads on a bottom surface of the semiconductor substrate,
wherein each of the semiconductor chips further comprises lower chip pads on a bottom surface of each of the semiconductor chips, and
wherein a third width of each of the lower substrate pads is greater than a fourth width of each of the lower chip pads.

18. The semiconductor package of claim 12, wherein the second semiconductor chip comprises a chip, a type of the chip being same as a type of each of the first semiconductor chips.

19. The semiconductor package of claim 12, wherein a number of the first semiconductor chips included in the chip stack ranges from 3 to 15.

20. A semiconductor package, comprising:
a substrate;
first semiconductor chips on the substrate; and
a second semiconductor chip on an uppermost first semiconductor chip of the first semiconductor chips,
wherein each of the first semiconductor chips comprises:
upper pads on a top surface each of the first semiconductor chips;
first lower pads on a bottom surface each of the first semiconductor chips; and
first vias vertically penetrating the first semiconductor chips and connecting the upper pads to the first lower pads, respectively,
wherein the second semiconductor chip comprises second lower pads a bottom surface of the second semiconductor chip,
wherein first terminals on the first lower pads are between a lowermost first semiconductor chip of the first semiconductor chips and the substrate,
wherein a first thickness of each of the first semiconductor chips is equal to a second thickness of the second semiconductor chip,
wherein side surfaces of the first semiconductor chips are coplanar to a side surface of the second semiconductor chip, and
wherein the second thicknesses of the semiconductor chips range from 20 μm to 40 μm.
